(19) United States
(12) Patent Application Publication
(10) Pub. No.: US 2017/0148652 A1
(43) Pub. Date: May 25, 2017

(54) SPIN CHUCK WITH IN SITU TEMPERATURE MONITORING

(71) Applicant: LAM RESEARCH AG, VILLACH (AT)

(72) Inventors: Reinhold HIPP, Villach-Landskron (AT); Helmut Marco LOY, Wernberg (AT)

(73) Assignee: LAM RESEARCH AG

(21) Appl. No.: 14/947,830

(22) Filed: Nov. 20, 2015

(51) Int. Cl. H01L 21/67; H01L 21/687

(52) U.S. Cl. CPC H01L 21/67248; H01L 21/68735

(57) ABSTRACT

A device for processing wafer-shaped articles comprises a rotary chuck mounted for rotation within a surrounding enclosure. The rotary chuck has mounted therein at least one sensor, a microprocessor connected to the at least one sensor so as to receive output signals therefrom, and a wireless transmitter connected to the microprocessor so as to receive output signals therefrom and transmit signals exteriorly of the device.

### BACKGROUND OF THE INVENTION

1. Field of the Invention

The invention relates generally to an apparatus for processing wafer-shaped articles, such as semiconductor wafers, and more particularly relates to such an apparatus comprising a spin chuck comprising an in situ temperature monitoring capability.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531.

It can be important to monitor process conditions occurring during wafer processing, so as to maintain the process parameters within desired specifications. One technique for monitoring process conditions involves the use of a test wafer that is equipped with sensors and is connected via a conductor to a transceiver that reads out the sensed data and communicates that data to a monitoring station, as described for example in U.S. Pat. No. 6,889,568.

It would be desirable, however, to be able to monitor wafer processing conditions in situ, during processing of an actual work piece rather than a test wafer. It would furthermore be desirable to enable such monitoring with a system that requires a minimum of intervention to the processing environment.

### SUMMARY OF THE INVENTION

Thus, in one aspect, the present invention relates to a device for processing wafer-shaped articles, comprising a rotary chuck mounted for rotation within a surrounding enclosure. The rotary chuck has mounted therein at least one sensor, a microprocessor connected to the at least one sensor so as to receive output signals therefrom, and a wireless transmitter connected to the microprocessor so as to receive output signals therefrom and transmit signals exteriorly of the device.

In preferred embodiments of the device according to the present invention, the rotary chuck comprises a circular series of pins positioned so as to contact an edge region of a wafer-shaped article of a predetermined diameter.

In preferred embodiments of the device according to the present invention, the circular series of pins projects from an upper surface of the rotary chuck, and the at least one sensor, the microprocessor and the wireless transmitter are mounted beneath the upper surface of the rotary chuck.

In preferred embodiments of the device according to the present invention, a battery is mounted in the rotary chuck and supplies power to at least the microprocessor and the wireless transmitter.

In preferred embodiments of the device according to the present invention, a coil is mounted in the rotary chuck and is electrically connected to the battery so as to permit the battery to be recharged by a current induced wirelessly in the coil.

In preferred embodiments of the device according to the present invention, a magnet is mounted in a stationary manner within the enclosure and adjacent the rotary chuck such that upon rotation of the rotary chuck a current is induced in the coil.

In preferred embodiments of the device according to the present invention, a capacitor is mounted in the rotary chuck and is connected to at least the microprocessor and the wireless transmitter.

In preferred embodiments of the device according to the present invention, a coil is mounted in the rotary chuck and is electrically connected to the capacitor so as to permit the capacitor to be charged by a current induced wirelessly in the coil.

In preferred embodiments of the device according to the present invention, a magnet is mounted in a stationary manner within the enclosure and adjacent the rotary chuck such that upon rotation of the rotary chuck a current is induced in the coil.

In preferred embodiments of the device according to the present invention, the at least one sensor, the microprocessor and the wireless transmitter are positioned such that their weight is distributed evenly with respect to an axis of rotation of the rotary chuck.

In preferred embodiments of the device according to the present invention, the at least one sensor comprises at least three sensors positioned beneath an upper surface of the rotary chuck and symmetrically with respect to an axis of rotation of the rotary chuck.

In preferred embodiments of the device according to the present invention, the at least one sensor comprises at least one temperature sensor.

In preferred embodiments of the device according to the present invention, the at least one sensor comprises at least one first temperature sensor that senses temperature by contact with an object whose temperature is to be sensed, and at least one second temperature sensor that senses temperature without contacting an object whose temperature is to be sensed.

In preferred embodiments of the device according to the present invention, a control station is positioned exteriorly of the enclosure, the control station comprising a controller for controlling operations of the rotary chuck, the control station further comprising a wireless receiver that receives signals from the wireless transmitter.

In preferred embodiments of the device according to the present invention, the wireless transmitter is a Bluetooth transceiver.

In preferred embodiments of the device according to the present invention, the at least one sensor comprises a g-force sensor. Alternatively, PT100 or PT1000 sensors may be used for temperature measurement, and/or a humidity sensor or an infrared temperature sensor may also be used.

In preferred embodiments of the device according to the present invention, the at least one sensor comprises a thermocouple.

In another aspect, the present invention relates to a rotary chuck for processing wafer-shaped articles, comprising a chuck body having mounted therein at least one sensor, a microprocessor connected to the at least one sensor so as to receive output signals therefrom, and a wireless transmitter connected to the microprocessor so as to receive output signals therefrom and transmit signals to a remote receiver.

In preferred embodiments of the rotary chuck according to the present invention, the chuck body comprises a circular series of pins positioned so as to contact an edge region of a wafer-shaped article of a predetermined diameter.

In preferred embodiments of the rotary chuck according to the present invention, the circular series of pins projects from an upper surface of the chuck body, and the at least one sensor, the microprocessor and the wireless transmitter are mounted beneath the upper surface of the chuck body.

In preferred embodiments of the rotary chuck according to the present invention, a battery is mounted in the chuck body and supplies power to at least the microprocessor and the wireless transmitter.

In preferred embodiments of the rotary chuck according to the present invention, a coil is mounted in the chuck body and is electrically connected to the battery so as to permit the battery to be recharged by a current induced wirelessly in the coil.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is an explanatory cross-sectional side view of an apparatus according to a first embodiment of the invention;

FIG. 2 is an explanatory cross-sectional side view of an apparatus according to a second embodiment of the invention;

FIG. 3 is a plan view of the upper side of the plate 28 shown in FIG. 1; and

FIG. 4 is a plan view of the lower side of the plate 28 shown in FIG. 1.

### DETAILED DESCRIPTION OF PREFERRED EMBODIMENTS

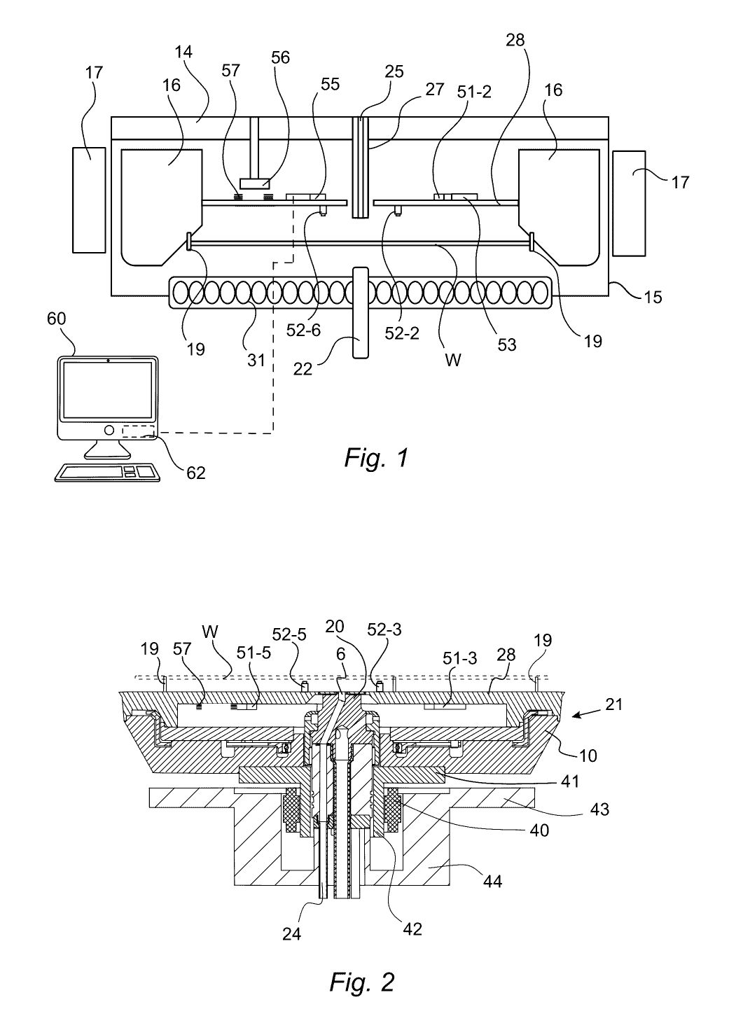

Referring now to FIG. 1, a device for treating surfaces of wafer-shaped articles according to a first embodiment of the invention comprises a closed process chamber 15, in which is arranged an annular spin chuck 16. Spin chuck 16 is a magnetic rotor that is surrounded by a magnetic stator 17 positioned outside the chamber 15, so that the magnetic rotor is freely rotating and levitating within the chamber 15 without touching the chamber walls. The chamber 15 is closed at its upper end by lid 14 rigidly secured thereto.

Further structural details of such a magnetic rotor chuck are described, for example, in commonly-owned U.S. patent application publication no. 2013/0134128.

The annular spin chuck 16 has a circular series of downwardly-depending gripping pins 19, which releasably hold a wafer W during processing. A lower dispense unit 22 is provided so as to supply liquid and/or gas to the side of the wafer W that faces downwardly within chamber 15. A heater 31 is disposed within the chamber 15, so as to heat the wafer W to a desired temperature depending upon the process being performed. Heater 31 preferably comprises a multitude of blue LED lamps, whose radiation output tends to be absorbed preferentially by silicon wafers relative to the components of the chamber 15.

An upper dispense unit comprises an outer gas conduit 27 and an inner liquid conduit 25 arranged coaxially within the outer gas conduit 25. Conduits 25, 27 both traverse the lid 14, and permit liquid and gas to be supplied to the side of the wafer W that faces upwardly within chamber 15.

A plate 28 is rigidly secured to the annular spin chuck 16, or in the alternative may be formed integrally therewith. Plate 28 therefore rotates with the spin chuck 16 and is a part of the spin chuck 16. The upper dispense unit passes through a central opening formed in plate 28. Plate 28 may comprise additional through apertures (not shown), so as to act as a gas showerhead for dispensing gas in a distributed manner into the chamber 15.

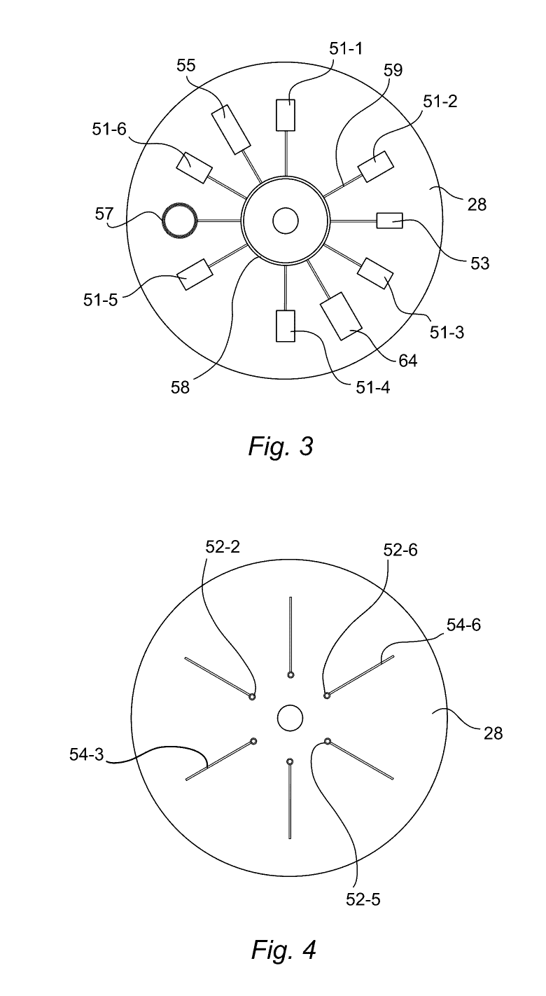

Plate 28 carries various process monitoring equipment, as shown more fully in FIGS. 3 and 4. In this embodiment, plate 28 carries six temperature sensors 52-1, 52-2, 52-3, 52-4, 52-5, 52-6, which are positioned on the side of the plate 29 that faces the wafer W, which in this case is the downwardly-facing side of plate 28. Temperature sensors 52-1 . . . 52-6 may be of the contact or non-contact type, or they may be a combination of both types. A preferred example of a contact type temperature sensor is a thermocouple. It will be understood that a “contact” sensor in this context does not connote a sensor that contacts the wafer W, but rather a sensor that reads the temperature of the ambient with which it is in contact. A preferred example of a non-contact temperature sensor is an infrared temperature sensor.

Temperature sensors 52-1, 52-2, 52-3, 52-4, 52-5, 52-6 each provide a signal representing the sensed temperature to respective conductors 54-1, 54-2, 54-3, 54-4, 54-5, 54-6, as shown in FIG. 4, which conductors pass through the plate 28 and are joined with the conductors 58 and 59 formed on the opposite side of plate 28, as shown in FIG. 3.

In particular, each sensor 52-1, 52-2, 52-3, 52-4, 52-5, 52-6 thereby provides its signal output to its respective sensor IC 51-1, 51-2, 51-3, 51-4, 51-5, 51-6, which processes and outputs a temperature readout signal via its respective conductor 59 to the circular bus 58. Bus 58 provides for communication between sensor ICs 51-1, . . . 51-6, and microprocessor 53 and Bluetooth transceiver 55. Bus 58 also allows these components to be powered via battery 64, which in turn can be charged by current induced wirelessly in the induction coil 57.

The components shown in FIG. 3 are mounted on the plate that faces away from the wafer W undergoing processing, which in the case of FIG. 1 is the upwardly-facing surface of plate 28. One or more of the sensors 52-1, 52-2, 52-3, 52-4, 52-5, 52-6 may be a g-force sensor rather than a temperature sensor. One or more of the sensors 52-1, 52-2, 52-3, 52-4, 52-5, 52-6 may be, instead of a temperature sensor, a sensor of processing chamber pressure, gas flow rate within the chamber 15, gaseous chemical composition within the chamber, ion current density, ion current energy, light energy density, and vibration of the wafer, in addition to or instead of a g-force sensor.

The outputs of sensor ICs 51-1, . . . 51-6 are supplied to microprocessor 53, which integrates the data and provides an output to Bluetooth transceiver 55. As shown in FIG. 1, Bluetooth transceiver 55 communicates wirelessly with the Bluetooth transceiver 62 of a control station 60. The data supplied to control station 60 via Bluetooth transceivers 55, 62 may thus be used to control various process parameters, such as duration of heating, speed and duration of rotation of the spin chuck, timing and duration of dispensing of process liquids, etc.

Battery 64 may instead be a capacitor that is charged via the induction coil 57. In FIG. 1, an embodiment is shown wherein a magnet 56 is mounted in a stationary manner within the chamber 15, and adjacent the rotary chuck 16 such that a current is induced in the coil 57 when the chuck is rotated. This embodiment therefore has the advantage of generating the power necessary for the in situ monitoring system.

FIG. 2 shows an alternative embodiment in which the chuck is rotated by a conventional electric motor. The chuck 21 of FIG. 2 comprises gripping fingers 19 extending upwardly from the chuck, which engage the peripheral edge of a wafer W to position the wafer a fixed distance above the chuck's upper surface.

A treatment liquid dispenser comprises liquid conduit 24 which extends axially through a central bore in chuck 10 to a liquid nozzle 6 located at the upper surface of the chuck. Liquid conduit 24 and liquid nozzle 6 are adapted to conduct one or more treatment liquids to the back surface of a wafer, preferably while the wafer W and chuck 10 are rotating.

The spin chuck 21 includes a non-rotating nozzle head 20 and a base body 10, which is mounted onto a rotating support plate 41. The support plate 41 is connected to a rotating hollow shaft 42 (rotor), which is part of a hollow shaft motor 40. The hollow shaft motor has an outer stator 40 and an inner rotor. The stator 40 is connected to a machine frame part 43, 44 with a frame plate 43 and a connecting part 44. The cylinder-like non-rotating nozzle head 20 is connected to the connecting part 44.

Plate 28 is integrated into the upper cover of chuck 21 in this embodiment. Thus, for example, each of the gripping pins 19 passes through a corresponding opening formed in the upper cover. However, the layout of the monitoring system on plate 28 in this embodiment is the same as in the preceding embodiment. The main difference is that, because the plate 28 faces a downwardly-facing surface of the wafer W, the components shown in FIG. 3 are on the lower surface of plate 28 and the components shown in FIG. 4 are on the upper surface. Other components of the preceding embodiment, e.g. the stationary magnet and surrounding process chamber, are omitted for ease of reference.

While the present invention has been described in connection with various preferred embodiments thereof, it is to be understood that those embodiments are provided merely to illustrate the invention, and that the invention is not limited to those embodiments, but rather includes that which is encompassed by the true scope and spirit of the appended claims.

What is claimed is:

1. A device for processing wafer-shaped articles, comprising a rotary chuck mounted for rotation within a surrounding enclosure, said rotary chuck having mounted therein at least one sensor, a microprocessor connected to said at least one sensor so as to receive output signals therefrom, and a wireless transmitter connected to the microprocessor so as to receive output signals therefrom and transmit signals exteriorly of said device.

2. The device according to claim 1, wherein said rotary chuck comprises a circular series of pins positioned so as to contact an edge region of a wafer-shaped article of a predetermined diameter.

3. The device according to claim 2, wherein said circular series of pins projects from an upper surface of said rotary chuck, and wherein said at least one sensor, said microprocessor and said wireless transmitter are mounted beneath said upper surface of said rotary chuck.

4. The device according to claim 1, further comprising a battery mounted in said rotary chuck and supplying power to at least said microprocessor and said wireless transmitter.

5. The device according to claim 4, further comprising a coil mounted in said rotary chuck and electrically connected to said battery so as to permit said battery to be recharged by a current induced wirelessly in said coil.

6. The device according to claim 5, further comprising a magnet mounted in a stationary manner adjacent said rotary chuck such that upon rotation of said rotary chuck a current is induced in said coil.

7. The device according to claim 1, further comprising a capacitor mounted in said rotary chuck and connected to at least said microprocessor and said wireless transmitter.

8. The device according to claim 7, further comprising a coil mounted in said rotary chuck and electrically connected to said capacitor so as to permit said capacitor to be charged by a current induced wirelessly in said coil.

9. The device according to claim 8, further comprising a magnet mounted in a stationary manner adjacent said rotary chuck such that upon rotation of said rotary chuck a current is induced in said coil.

10. The device according to claim 1, wherein said at least one sensor, said microprocessor and said wireless transmitter are positioned such that their weight is distributed evenly with respect to an axis of rotation of said rotary chuck.

11. The device according to claim 1, comprising at least three sensors positioned beneath an upper surface of said rotary chuck and symmetrically with respect to an axis of rotation of said rotary chuck.

12. The device according to claim 1, wherein said at least one sensor comprises at least one temperature sensor.

13. The device according to claim 1, wherein said at least one sensor comprises at least one first temperature sensor that senses temperature by contact with an object whose temperature is to be sensed, and at least one second temperature sensor that senses temperature without contacting an object whose temperature is to be sensed.

14. The device according to claim 1, further comprising a control station positioned exteriorly of said enclosure, said control station comprising a controller for controlling operations of said rotary chuck, said control station further comprising a wireless receiver that receives signals from said wireless transmitter.

15. The device according to claim 1, wherein said wireless transmitter is a Bluetooth transceiver.

16. The device according to claim 1, wherein said at least one sensor comprises a g-force sensor.

17. The device according to claim 1, wherein said at least one sensor comprises a thermocouple.

18. A rotary chuck for processing wafer-shaped articles, comprising a chuck body having mounted therein at least one sensor, a microprocessor connected to said at least one sensor so as to receive output signals therefrom, and a wireless transmitter connected to the microprocessor so as to receive output signals therefrom and transmit signals to a remote receiver.

19. The rotary chuck according to claim 18, wherein said chuck body comprises a circular series of pins positioned so as to contact an edge region of a wafer-shaped article of a predetermined diameter.

20. The rotary chuck according to claim 19, wherein said circular series of pins projects from an upper surface of said chuck body, and wherein said at least one sensor, said microprocessor and said wireless transmitter are mounted beneath said upper surface of said chuck body.

21. The rotary chuck according to claim 18, further comprising a battery mounted in said chuck body and supplying power to at least said microprocessor and said wireless transmitter.

22. The rotary chuck according to claim 21, further comprising a coil mounted in said chuck body and electrically connected to said battery so as to permit said battery to be recharged by a current induced wirelessly in said coil.
